(19) United States
(12) Patent Application Publication
(10) Pub. No.: US 2008/0202795 A1
(43) Pub. Date: Aug. 28, 2008

(54) Method of Improving the Strength of a Spot-Welded Joint Between Fine Enameled Wire and Circuit Board

(75) Inventor: Xiangyang Yin, Guangzhou (CN)

Correspondence Address: WANG & HO, 66 HILLTOP ROAD, MILLINGTON, NJ, 07946, US

(73) Assignee: Mornsun Guangzhou Science & Technology Ltd., Guangzhou (CN)

(21) Appl. No.: 11/573,295

(22) PCT Filed: Apr. 11, 2005
(86) PCT No.: PCT/CN2005/000478

§ 371 Date: Feb. 6, 2007

(30) Foreign Application Priority Data
Aug. 13, 2004 (CN) 200410051069.3

(51) Int. Cl. H05K 1/00; H05K 3/34

(52) U.S. Cl. 174/250; 29/840

(57) ABSTRACT

A method for improving the reliability of the welding spot between thin enameled wires and an electronic board and thus securing the connection therebetween, by pulling the terminals of the enameled wires to the back of the electronic board and thereby creating a bearing point on the structure of the board. The bearing point, positioned between the welding spot and the wire terminal, effectively prevents the external forces of stress from directly acting on the welding spot when the terminals of the wire are pulled, swung up and sown, or subjected to other external pulling forces.

### CROSS REFERENCE TO RELATED APPLICATION

This application is the national phase of PCT Application No. WO2005CN00478, filed Apr. 11, 2005, which claims priority to Chinese Patent Application No. CN20041051069, filed Aug. 13, 2004, the contents of which are hereby incorporated by reference.

### FIELD OF THE INVENTION

This invention is related to a welding method. In particular, it relates to a method of improving the reliability of a welding spot between an electronic board and a thin enameled wire, especially when the wire used in the spot-welding has a diameter less than 0.1 mm.

### BACKGROUND OF THE INVENTION

At the present time, the connection between a circuit board and thin enameled wires (with diameters less than 0.1 mm) is normally made through spot-welding (SW), where the thin wire can be a single wire or a bundle consisting of multiple wires. The SW electronic spot welder is capable of welding enameled wires without first removing the outer layer of insullac. The fundamental principle of electronic spot welding is that an intense current is loaded on the workpiece between two spot electrodes (or parallel electrodes) within a short period of time to form a welding spot under the resistance-generated heat and the pressure applied on the workpiece. The detailed operating setup is illustrated in FIG. 1, where the three parameters, i.e., the welding pressure, the intensity and duration of the outputting pulse are set on the SW welder according to the diameter of enameled wires 8 and the requirements of a particular welding workpiece; the micro-switch is triggered to deliver electric current when the pressure loaded on the welding head reaches the pre-set value; and the tip of parallel electrodes 7 will produce sparks when electrified because of the resistance placed between the parallel electrodes 7. In the area close to the tip of electrodes, some insullac of the wire is burned out and some insullac shrinks and recedes to expose the naked wire. The continuous welding pressure drives a large amount of current into the exposed wire and metal substrate 9, where the electricity transforms into heat in a way that accomplishes both insullac removal and spot welding within a single pulse.

After the above welding process, the enameled wire is usually directly pulled out for use (see FIG. 2), thereby subjecting point A (where the wire and welding spot are connected) to various types of stress. For example, when the wire is pulled, swung up and down, or twisted, it tends to break off from point A or gets damaged due to the increased hardness and reduced plasticity and tenacity which have occurred under the harsh welding condition of high pressure, heating and air cooling. As a result, it brings unreliability to the electronic circuit.

### SUMMARY OF THE INVENTION

The present invention is aimed to provide a method for improving the reliability of the welding spot between the electronic board and thin enameled wires which have a diameter of less than 0.1 mm. The method not only improves the reliability of the welding connection between thin enameled wires and the electronic board, but also effectively prevents the wire from getting damaged or breaking off from the welding spot.

This and other objects of the present invention are realized through the technical solutions described in the following.

The essence of the method of the present invention is that after being spot-welded to the electronic board the thin enameled wire is pulled to the back of the electronic board, where it is then used or connected to other components. In this way, at least a new bearing point is created. The bearing point is located on the structure of the electronic board itself in a way that the stress is transferred to this bearing point, rather than to the welding spot (point A). With this bearing point, the external forces, such as, tensile stress, up-and-down swing and torsion loaded on the welded wires, will not directly act on or weaken the welding spot, thereby avoiding exposing the weakest point (i.e., the welding spot) to the external forces and protecting the welding connection between the wires and the electronic board and effectively preventing the wires from being damaged or breaking off from the welding spot.

According to another aspect of the present invention, the connecting point between the thin enameled wire and the electronic board is positioned close to the surface of electronic board so that it is convenient for bending the thin enameled wire around the electronic board.

According to another aspect of the present invention, the bearing point may be part of the structure of the circuit board itself such as any suitable holes and openings, or it may be additional small structures added to the circuit board for the purpose of bending the wires. Further aspects of the present inventions are described as follows. The thin enameled wire may be directly bended around the edge of the electronic board without going through an opening on the circuit board. For better fixing or securing the wire at a particular position, one or more flutes or notches may be made at the edge of the electronic board, through which the thin enameled wire is bended around the electronic board. Alternatively, one or more through-holes may be made on the electronic board, by which the enameled wire can be bended and pulled through to the back of the electronic board.

The advantages provided by the present invention may be summarized as the following: (1) it can effectively prevent the wires from being damaged or breaking off from the welding spot by external forces to avoid potential problems to the electronic circuit and ensure its reliability; (2) its implementation is easy and convenient, involving only a simple structure.

### BRIEF DESCRIPTION OF DRAWINGS

FIG. 1 is a diagram showing a presently used setup for electronic spot welding.

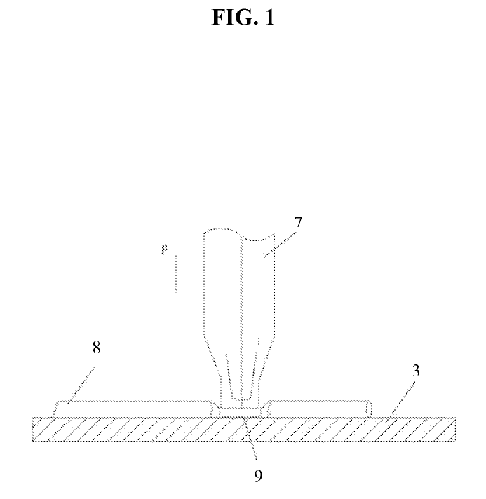

FIG. 2 shows the prior art arrangement between the thin enameled wire and the electronic board.

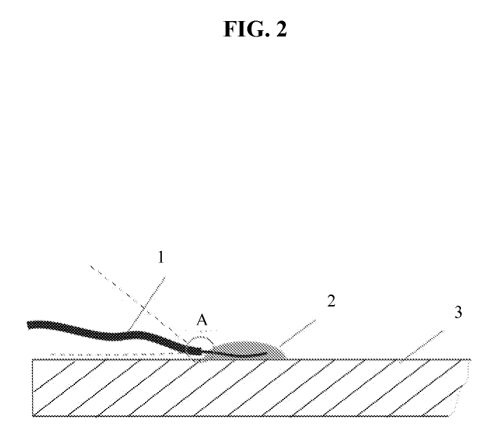

FIG. 3 shows a particular embodiment of the present invention.

FIG. 4 shows a second particular embodiment of the present invention.

FIG. 5 shows a third particular embodiment of the present invention.

### DETAILED DESCRIPTION OF PARTICULAR EMBODIMENTS

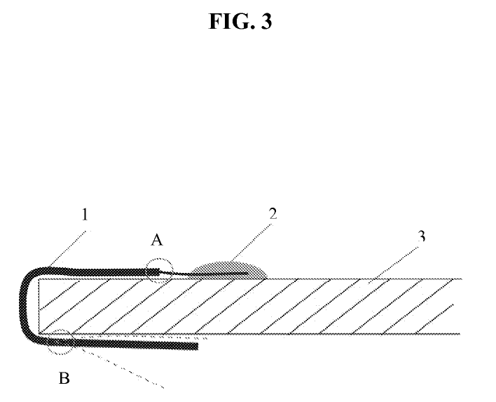

FIG. 3 is one embodiment of the present invention, in which the thin enameled wire 1 is welded to electronic board 3 through welding spot 2; the thin enameled wire 1 is intersected with welding spot 2 at point A, which is located near the surface of electronic board 3. The thin enameled wire 1 is directly bended around the edge of the electronic board 3 and pulled to the back of the electronic board (the side opposite to the welding spot) where it may connect to other components. In this way, pivot B is formed at the edge of the electronic board and the swung end 1′ (i.e., the terminal for connection with other components) uses pivot B as the bearing point. It prevents the tensile stress and the external forces of up-and-down swing and torsion on the thin enameled wire from being directly loaded on point A. Thus it effectively protects the welding connection between the thin enameled wire and the electronic board and prevents the wire from getting damaged or breaking off from the welding spot.

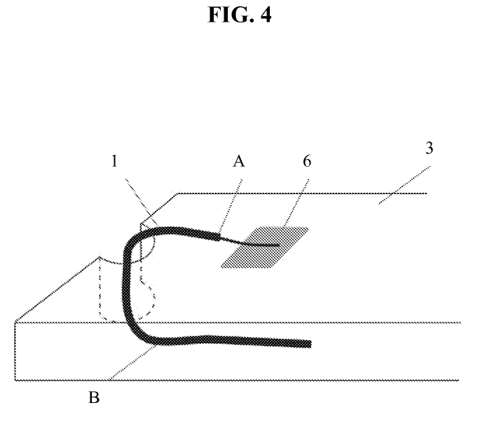

FIG. 4 is a second embodiment of the present invention. It differs from the above embodiment in that the thin enameled wire is welded to a piece of metal sheet 6; a notch 4 is made on the edge of the electronic board 3; the thin enameled wire 1 is bended around the electronic board through the notch.

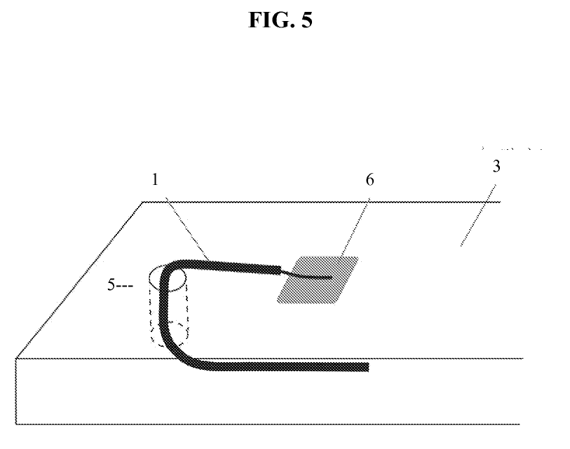

FIG. 5 is a third embodiment of the present invention. It differs from the embodiment shown in FIG. 3 in that the thin enameled wire is welded to a piece of metal sheet 6; a through-hole 5 is made on the electronic board 3; the thin enameled wire 1 is bended and pulled towards the back of the electronic board through the through-hole.

1-5. (canceled)

6. A method of improving the reliability of welding spot involving a thin enameled wire, comprising a step of pulling a terminal of an enameled wire being spot-welded to one side of a circuit board towards an opposite side of said circuit board where it used or connected to another component.

7. The method according to claim 6, wherein said enameled wire intersects with a welding spot at location close to the surface of the circuit board.

8. The method according to claim 6, wherein said enameled wire is bended around an edge of said circuit board.

9. The method according to claim 7, wherein said enameled wire is bended around an edge of said circuit board.

10. The method according to claim 6, wherein there is a notch on an edge of said circuit board and said enameled wire is bended around said edge via said notch.

11. The method according to claim 7, wherein said enameled wire is bended around said edge of said circuit board via a notch located on said edge.

12. The method according to claim 6, wherein there is a through-hole on said circuit board and said enameled wire is bended and pulled through said through-hole to said opposite side of said circuit board.

13. The method according to claim 7, wherein there is a through-hole on said circuit board and said enameled wire is bended and pulled through said through-hole to said opposite side of said circuit board.

14. The method according to claim 6, wherein said enameled wire has a diameter of 0.1 mm or less.

15. The method according to claim 7, wherein said enameled wire has a diameter of 0.1 mm or less.

16. An electronic device, comprising an enameled wire and a circuit board, said enameled wire having a first terminal and a second terminal and said circuit board having a first side and a second side; said first terminal of said enameled wire being connected to said circuit board via a welding spot disposed on said first side of said circuit board and said second terminal of said enameled wire being bended and pulled to said second side of said circuit board where is further consumed or connected to another component.

17. The electronic device of claim 16, wherein said second terminal of said enameled wire is pulled to said second side of said circuit board around an edge of said circuit board.

18. The electronic device of claim 17, wherein said second terminal of said enameled wire is pulled to said second side of said circuit board via a notch located on an edge of said circuit board.

19. The electronic device of claim 16, wherein said second terminal of said enameled wire is pulled to said second side of said circuit board through a through-hole deposed on said circuit board.

20. The electronic device of claim 16, wherein said enameled wire has a diameter of 0.1 mm or less.
